(19) United States
(12) Patent Application Publication
(10) Pub. No.: US 2025/0392305 A1
(43) Pub. Date: Dec. 25, 2025

(54) BIPOLAR JUNCTION DEVICE, AND METHODS AND SWITCH ASSEMBLIES USING SAME

(71) Applicant: IDEAL POWER INC., Austin, TX (US)

(72) Inventors: Jiankang BU, Austin, TX (US); Mudit KHANNA, Austin, TX (US); R. Daniel BRDAR, Driftwood, TX (US)

(73) Assignee: IDEAL POWER INC., Austin, TX (US)

(21) Appl. No.: 19/190,985

(22) Filed: Apr. 28, 2025

Related U.S. Application Data
(60) Provisional application No. 63/661,656, filed on Jun. 19, 2024.
(60) Provisional application No. 63/704,798, filed on Oct. 8, 2024.

(51) Int. Cl. H03K 17/66; H10D 18/65

(52) U.S. Cl. CPC H03K 17/665; H10D 18/655

(57) ABSTRACT

Bipolar junction device, and methods and switch assemblies using same. At least one example is a bipolar junction device that includes a substrate defining a first side and a second side, and a field-effect structure defined on the first side. The field-effect structure includes a channel region, a gate region in operational relationship to the channel region, and electrically insulated from the channel region, and a cathode region forming a junction with the channel region. A bipolar junction structure defined on the second side includes an injection region forming a junction with the substrate and an anode region in operational relationship to the substrate.

### CROSS-REFERENCE TO RELATED APPLICATIONS

This application claims the benefit of U.S. Provisional Application No. 63/661,656, filed on Jun. 19, 2024 and U.S. Provisional Application No. 63/704,798, filed Oct. 8, 2024. The entire disclosures of the applications referenced above are incorporated herein by reference.

### FIELD

The present disclosure relates to switch assemblies using bipolar junction devices.

### BACKGROUND

Various electrical devices, and combinations of electrical devices, operate as “unidirectional” devices. That is, in the context of conduction of electrical current, unidirectional means selective conduction when the device/assembly is forward biased, and non-selective conduction when the device/assembly is reverse biased. One example of such an electrical device is a field effect transistor (FET) with an internal body diode. When the voltage applied to the FET makes the body diode conductive, current non-selectively flows through the device; however, with the opposite applied voltage, the body diode is non-conductive, and current only flows through the FET when the gate is asserted. Many electrical circuits, both in the small-signal electronics and the power electronics, are designed and constructed based on such unidirectional devices and/or operation.

In other cases, electrical devices or combinations of electrical devices operate as “bidirectional” devices. That is, in the context of conduction of electrical current, bidirectional means selective conduction when the device/assembly is forward biased, and also selective conduction when the device/assembly is reverse biased. One example is a doubled-sided, double-base bipolar junction device (BJT) marketed under the brand name B-TRAN®, available from Ideal Power Inc. of Austin, Texas.

### SUMMARY

A bipolar junction device includes a substrate defining a first side and a second side and a field-effect structure defined on the first side. The field-effect structure includes a channel region, a gate region in operational relationship to the channel region, and electrically insulated from the channel region, and a cathode region forming a junction with the channel region. A bipolar junction structure defined on the second side includes an injection region forming a junction with the substrate and an anode region in operational relationship to the substrate.

In other features, the gate region includes a metal electrically insulated from the channel region. The substrate is N-type, the channel region is P-type and the cathode region is N-type. The injection region is P-type and the anode region is N-type. The injection region has a depth, after activation, of about 10 microns. The injection region has a depth, after activation, of about 5 microns. The bipolar junction device further includes a cathode metal electrically contacting the cathode region and the channel region. The cathode metal forms an ohmic contact with the cathode region.

A switch assembly includes an upper terminal, a lower terminal, and a control terminal and a bipolar junction device. The bipolar junction device includes a channel region on a first side of a substrate, the channel region coupled to the lower terminal, a cathode region in operational relationship to the channel region, a gate region in operational relationship to the both the channel region and the cathode region, an anode region on a second side of the substrate opposite the first side, the anode region coupled to the upper terminal, and an injection region on the second side of the substrate. A driver coupled to control terminal, the cathode region, and the gate region, is configured to, during periods of time when the switch assembly is forward biased and the control terminal is asserted, arrange the bipolar junction device to conduct a forward current from the upper terminal, through the anode region, and to the lower terminal, and during periods of time when the switch assembly is forward biased and the control terminal is de-asserted, arrange the bipolar junction device to block current from the upper terminal to the lower terminal.

In other features, during periods of time when the switch assembly is reverse biased, the bipolar junction device non-selectively conducts a reverse current from the lower terminal, to the cathode region, and then to the upper terminal. The driver is further configured to, during periods of time when the switch assembly is forward biased and the control terminal is asserted, inject charge carriers into substrate by way of the injection region. The driver is further configured to, during periods of time when the switch assembly is reverse biased, inject charge carriers into the substrate by way of the injection region.

A semiconductor device includes a substrate defining a first side and a second side, an upper field-effect transistor on the first side, the upper field-effect transistor defines an upper channel region, an upper gate structure in operational relationship to the upper channel region, and an upper drain region that forms a junction with the upper channel region, an upper injection region on the first side, a lower field-effect transistor on the second side, the lower field-effect transistor defines a lower channel region, a lower gate structure in operational relationship to the lower channel region, and a lower drain region that forms a junction with the lower channel region, a lower injection region on the second side, and a drift region within in the substrate between the upper channel region and the lower channel region.

In other features, the upper field-effect transistor includes an upper ridge defined between a first trench region and a second trench region, the upper ridge defines a first sidewall associated with the first trench region, a second sidewall associated with the second trench region, and an upper crest, the upper drain region and the upper channel region within the upper ridge, an upper-drain metal disposed on the upper crest and electrically coupled to the upper drain region, and the upper gate structure disposed on the second sidewall in operational relationship to the upper channel region. The upper injection region is a doped region associated with a bottom of the first trench region.

In other features, the upper-drain metal is in ohmic contact with the upper drain region. The first trench region and the second trench region are at least one selected from a group includes: portions of an upper trench and portions of a first trench and a second trench, respectively. The lower field-effect transistor further includes a lower ridge defined between a third trench region and a fourth trench region, the lower ridge defines a third sidewall associated with the third trench region, a fourth sidewall associated with the fourth trench region, and a lower crest, the lower drain region and the lower channel region disposed within the lower ridge, a lower-drain metal disposed on the lower crest and electrically coupled to the lower drain region, the lower gate structure disposed on the fourth sidewall in operational relationship to the lower channel region. The lower injection region is a doped region associated with a bottom of the third trench region. The lower-drain metal is in ohmic contact with the lower drain region. The third trench region and the fourth trench region are at least one selected from a group including: portions of a lower trench; and portions of a first trench and a second trench, respectively.

In other features, the upper field-effect transistor includes an upper ridge defined between a first trench region and a second trench region, the upper ridge defines a first sidewall associated with the first trench region, a second sidewall associated with the second trench region, and an upper crest, the upper drain region and the upper channel region disposed within the upper ridge, an upper-drain metal disposed on the upper crest and electrically coupled to the upper drain region, the upper gate structure including a first gate structure within the first trench region and in operational relationship to the upper channel region, and a second gate structure within the second trench region and in operation relationship to the upper channel region. The first trench region defines an adjacent crest, and the upper injection region disposed within an adjacent crest.

In other features, the upper field-effect transistor includes a first trench defining a first sidewall associated with a first terrace, a second sidewall associated with a second terrace, and a bottom, the upper drain region and the upper channel region disposed within the substrate of the first terrace, an upper-drain metal disposed on the first terrace and electrically coupled to the upper drain region, and the upper gate structure including a first gate structure within the first trench and in operational relationship to the upper channel region. The upper injection region is a doped region associated with the bottom of the first trench.

In other features, the semiconductor device further includes an adjacent field-effect transistor on the first side, the adjacent field-effect transistor including an upper drain region and an upper channel region disposed within the substrate of the second terrace, an upper-drain metal disposed on the second terrace and electrically coupled to the upper drain region of the adjacent field-effect transistor, and an adjacent gate including a first gate structure within the first trench and in operational relationship to the upper channel region of the adjacent field-effect transistor.

In other features, the upper gate structure includes a metal electrically insulated from the upper channel region. The substrate is N-type, each of the upper and lower channel regions is P-type, and each of the upper and lower drain regions is N-type. The each of the upper and lower injection regions is P-type. The each of the upper and lower injection regions has a depth, after activation, of about 10 microns.

A switch assembly includes an upper terminal, a lower terminal, and a control terminal, and an electrically-controlled switch including a substrate defining a first side and a second side, an upper field-effect transistor disposed on the first side, the upper field-effect transistor defines an upper gate, and an upper drain coupled to the upper terminal, an upper injection region disposed on the first side and in operational to the upper field-effect transistor, a lower field-effect transistor disposed on the second side, the lower field-effect transistor defines a lower gate, and a lower drain coupled to the lower terminal, a lower injection region disposed on the second side and in operational relationship to the lower field-effect transistor, and a drift region disposed within the substrate between the upper field-effect transistor and the lower field-effect transistor. A driver coupled to control terminal, upper gate, the upper drain, the upper injection region, the lower gate, the lower drain, and the lower injection region is configured to, during periods of time when the switch assembly is forward biased and the control terminal is asserted, arrange the electrically-controlled switch to conduct a forward current from the upper terminal, through the electrically-controlled switch, and to the lower terminal, and inject charge carriers into the drift region by way of the upper injection region or the lower injection region.

In other features, the driver is further configured to, during periods of time when the switch assembly is forward biased and the control terminal is de-asserted, arrange the electrically-controlled switch to block current from the upper terminal to the lower terminal. The driver is further configured to, during periods of time when the switch assembly is forward biased and the control terminal is asserted, arrange the electrically-controlled switch to conduct a reverse current from the lower terminal, through the electrically-controlled switch, and to the lower terminal, and inject charge carriers into the drift region by way of the lower injection region. The driver is further configured to, during periods of time when the switch assembly is reverse biased and the control terminal is de-asserted, arrange the electrically-controlled switch to block current from the lower terminal to the upper terminal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

For a detailed description of example embodiments, reference will now be made to the accompanying drawings in which:

FIG. 1 shows a partial cross-sectional view of an example bipolar junction device;

FIGS. 2A-2E show example states of operation of a bipolar junction device;

FIG. 3 shows, in block diagram form, an example switch assembly;

FIG. 4 shows an example circuit symbol for a bipolar junction device;

FIG. 5 shows a partial block diagram, partial electrical schematic, of an example switch assembly;

FIG. 6 shows a partial cross-sectional view of an example semiconductor device;

FIG. 7 shows a partial cross-sectional view of an example semiconductor device;

FIG. 8 shows a partial cross-sectional view of another example semiconductor device;

FIGS. 9A-9E show a simplified version of the semiconductor device to describe operation of the device;

FIG. 10 shows, in block diagram form, an example switch assembly;

FIG. 11 shows an example circuit symbol for the semiconductor device; and

FIG. 12 shows a partial block diagram and partial electrical schematic of an example switch assembly.

### DEFINITIONS

Various terms are used to refer to particular system components. Different companies may refer to a component by different names-this document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or a direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” or “approximately” in reference to a recited parameter shall mean the recited parameter plus or minus ten percent (+/−10%) of the recited parameter.

“Thermally diffusing” or “thermal diffusion” shall mean a diffusion or activation step that takes place in a heated chamber (e.g., at 800° C. to 1150° C.).

“Laser annealing” or “rapid thermal annealing” (RTA) shall mean a diffusion or activation step in which the heat for diffusion or activation is provided by a laser incident upon the surface of the substrate. While the temperature of the wafer may reach to between and including 800° C. to 1150° C. during laser annealing, the depth penetration of the heat is less than thermal diffusion.

“Upper” in reference to component (e.g., upper collector-emitter) shall not be read to imply a location of the recited component with respect to gravity. Upper may be derived from location of the device in an example drawing.

“Lower” in reference to a component (e.g., lower collector-emitter, lower base) shall not be read to imply a location of the recited component with respect to gravity. Lower may be derived from location of the device in an example drawing.

“Ohmic contact” shall mean a non-rectifying electrical junction between two materials (e.g., a metal and a semiconductor).

“Controller” shall mean, alone or in combination, individual circuit components, an application specific integrated circuit (ASIC), a microcontroller with controlling software, a reduced-instruction-set computing (RISC) with controlling software, a digital signal processor (DSP), one or more processors or processing devices with controlling software, a programmable logic device (PLD), a field programmable gate array (FPGA), a programmable system-on-a-chip (PSOC), configured to read inputs and drive outputs responsive to the inputs, and/or other circuitry configured to perform associated functions.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various examples are directed to a bipolar junction device, and methods and switch assemblies using such a bipolar junction device. More particularly, various examples are directed to a bipolar junction device having a field effect structure on a first side of a substrate, and a bipolar junction structure on a second side the substrate. When the bipolar junction device is forward biased, a forward current through the bipolar junction device may be selectively controlled. Moreover, during periods of time when forward current is flowing, the voltage drop across the bipolar junction device may be lowered by injection of charge carriers into a drift region of the substrate. When the bipolar junction device is reverse biased, a reverse current non-selectively through the device. Thus, the example bipolar junction device is a unidirectional device. Moreover, during periods of time when reverse current is flowing, the voltage drop across the bipolar junction device may be lowered by injection of charge carriers into the drift region. The injection of charge carriers may make the voltage drop across the bipolar junction device lower than the voltage drop through an equivalently rated FET. The description now turns to an example bipolar junction device.

Other examples are directed to a semiconductor device that is bidirectional, and switch assemblies using such a semiconductor device. More particularly, various examples are directed to a semiconductor device constructed on a substrate and having upper field-effect transistors on an upper side, upper injection regions on the upper side, lower field-effect transistors on a lower side, and lower injection regions on the lower side. When the semiconductor device is forward biased, a forward current through the semiconductor device may be selectively controlled. Moreover, during periods of time when forward current is flowing, the voltage drop across the semiconductor device may be lowered by injection of charge carriers into a drift region of the substrate by way of the injection regions. When the semiconductor device is reverse biased, a reverse current through the semiconductor device may be selectively controlled. Moreover, during periods of time when reverse current is flowing, the voltage drop across the semiconductor device may be lowered by injection of charge carriers into the drift region. The description now turns to an example semiconductor device.

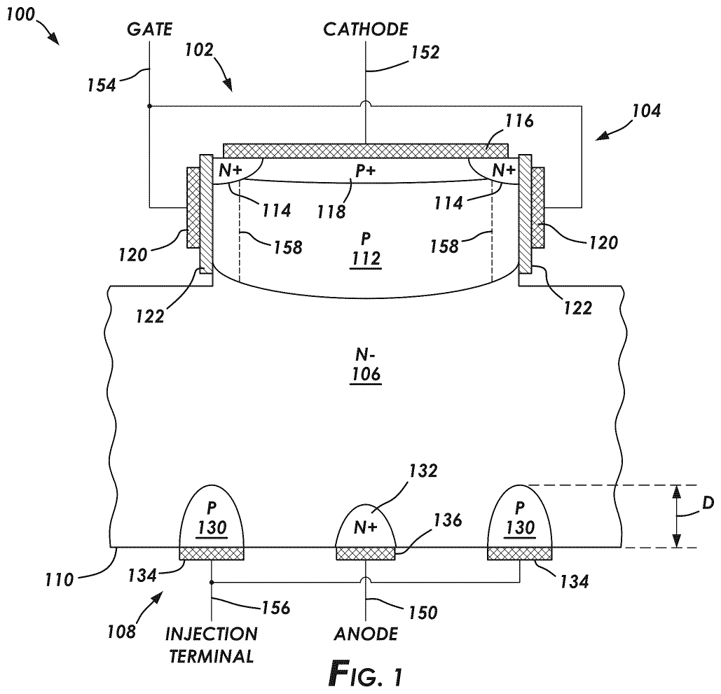

FIGS. 1-5 are generally directed to a bipolar junction device and methods and switch assemblies using such a bipolar junction device. FIG. 1 shows a partial cross-sectional view of an example bipolar junction device 100. In particular, FIG. 1 shows a cross-sectional view of a single cell of the bipolar junction device 100 comprising a field-effect structure 102 on an upper side 104 of a substrate 106, and a bipolar junction structure 108 on a lower side 110 of the substrate 106. The terms “upper” and “lower” are relational terms, which may be derived from the position of the structures/regions in the example figure. The terms “upper” and “lower” shall not be read to imply any location with respect to gravity. Referring initially to the upper side 104, the example field-effect structure 102 comprises a channel region 112 (e.g., a P-type region). As will be discussed in greater detail below, it is within the channel region 112 that a conductive channel is formed during periods of the time when the field-effect structure 102 is used to selectively control forward current through the bipolar junction device 100.

The field-effect structure 102 further comprises a cathode region 114 (e.g., N+) forming a junction with the channel region 112. FIG. 1, being a cross-sectional view, shows two instances of the cathode region 114 owing to the cell structure of the device. That is, in some cases, the cathode region 114 is a continuous region (e.g., circular, obround), and the cross-section view of FIG. 1 happens to show both sides of the continuous cathode region 114. In other cases, however, the cathode regions may be separate and distinct from each other.

In example cases, the cathode region 114 is electrically coupled to a cathode metal 116. In particular, the cathode metal 116 may be deposited on the upper side 104 at any suitable time during the construction of the bipolar junction device 100. In example cases, the cathode metal 116 forms an ohmic contact (e.g., non-rectifying contact) to or with the cathode region 114. Additional layers, including additional metal layers (e.g., titanium), may be present to form the ohmic contact, but those additional layers are not shown so as not to unduly complicate the figure.

Disposed in the region between the instances of the cathode region 114 is an example P-type region 118 (e.g., P+), and the example P-type region 118 may have the same or different doping characteristics than the channel region 112. The example cathode metal 116 may likewise be in electrical contact with the P-type region 118. In most cases, the electrical contact between the cathode metal 116 and the P-type region 118 is also an ohmic connection; however, a non-ohmic or rectifying (e.g., Schottky) connection is also contemplated, as such a rectifying connection will be forward biased during the non-selective reverse current flow from the cathode metal 116 into the bipolar junction device 100.

The field-effect structure 102 further comprises a gate region 120 in operational relationship to the channel region 112, and the gate region electrically isolated from the channel region 112. The cross-sectional view of FIG. 1 shows two instances of the gate region 120 owing to the cell structure of the device. That is, in some cases, the gate region 120 is a continuous region (e.g., circular, obround), and the cross-section view of FIG. 1 happens to show both sides of the continuous gate region 120. In other cases, however, the gate regions may be separate and distinct, but nevertheless electrically connected in operation. In some examples, the gate region 120 may be a metallic material, but in other cases the gate region may be polysilicon with high conductivity. An insulator 122 (e.g., oxide) may electrically isolate the gate region 120 from the cathode region 114.

Referring still to FIG. 1, and particularly to the bipolar junction structure 108 on the lower side 110, the example bipolar junction structure 108 comprises an injection region 130 and an anode region 132. The cross-sectional view of FIG. 1 shows two instances of the injection region 130 owing to the cell structure of the device. That is, in some cases the injection region 130 is a continuous region (e.g., circular, obround), and the cross-section view of FIG. 1 happens to show both sides of the continuous injection region 130. In other cases, the injection regions may be separate and distinct, but both instances nevertheless be electrically connected in operation. The example injection region 130 (e.g., P-type) forms a junction with the substrate 106 (e.g., N-type).

The depth of the injection region 130, after diffusion, may be dependent upon the overall voltage rating of the bipolar junction device 100. That is, for bipolar junction devices with higher voltage ratings (e.g., 1200V), the thickness of the substrate 106 during construction of the structures on both sides of the substrate 106 may be such that the thermal budgets are high. In such cases, the construction techniques may use “thick wafer” processing, such as thermal annealing to diffuse and/or activate the injection region 130. However, in cases in which the voltage ratings are lower (e.g., 400V or 600V), in order to reduce on-state voltage drop across the device, the substrate 106 may be thinned prior to construction of the bipolar junction structure 108. In such cases, the construction techniques may use “thin wafer” processing, such as laser annealing to diffuse and/or activate the injection region 130. In such cases, the depth of the injection region 130 may be shallower. In cases in which the injection region 130 is diffused and/or activated by way of thermal annealing, the depth D of diffusion may be about 10 microns. By contrast, in cases in which the injection region 130 is diffused and/or activated by way of laser annealing, the depth D of diffusion may be about 5 microns. Co-pending and commonly assigned U.S. Prov. App. No. 63/658,508 filed Jun. 11, 2024 and titled “Methods of Manufacturing Bipolar Junction Devices” discusses aspects of “thick wafer” processing for some structures, and “thin wafer” processing for other structures on the same wafer.

The example anode region 132 is disposed between the two instances of the injection region 130. For the example substrate being N-type, the anode region 132 is also N-type, though the doping may be higher (e.g., N+) compared the intrinsic doping of the substrate. As will be discussed in greater detail below, the anode region 132 is the path of main current flow, both for selectively-controlled forward current during forward bias of the bipolar junction device 100, and for reverse current during reverse bias of the bipolar junction device 100.

Still referring to FIG. 1, the injection region 130 and the anode region 132 are respectively associated with metal regions. In particular, the injection region 130 is associated with injection metal 134. The anode region 132 is associated with anode metal 136. Though the injection metal 134 and the anode metal 136 are shown as separate and distinct, in some cases a single metal layer is created or deposited on the lower side, and through photolithographic patterning for photoresist, and etching, the electrically isolated structures may be created. In example cases, the anode metal 136 forms an ohmic contact (e.g., non-rectifying contact) to or with the anode region 132. Additional layers, including additional metal layers (e.g., titanium), may be present to form the ohmic contact, but those additional layers are not shown so as not to unduly complicate the figure. In most cases, the electrical contact between the injection metal 134 and the injection region 130 is also an ohmic connection; however, a non-ohmic or rectifying (e.g., Schottky) connection is also contemplated, as such a rectifying connection will be forward biased during injection of charge carriers from the injection region 130 into the substrate 106.

The example bipolar junction device 100 thus defines four connections or terminals. These terminals may be electrically accessible, such as by way of external pins of packaging that encapsulates or encloses the bipolar junction device 100. In particular, the bipolar junction device defines an anode 150, a cathode 152, a gate 154, and an injection terminal 156.

For purposes of explanation, consider that an external voltage is applied to the bipolar junction device 100, with the cathode 152 having a higher voltage relative to the anode 150, hereinafter a “reverse bias.” Independent of the voltage applied to the gate 154, the bipolar junction device 100 conducts current from the cathode 152 to the anode 150. That is, during the example reverse bias of the overall device, the internal PN junction formed between the substrate 106 and the channel region 112 is forward biased, enabling current flow.

Now consider that an external voltage is applied to the bipolar junction device 100, with the anode 150 having a higher voltage relative to the cathode 152, hereinafter a “forward bias.” In the absence of a voltage on the gate 154, the bipolar junction device 100 blocks current flow. In particular, during the example forward bias of the overall device, the internal PN junction formed between the substrate 106 and the channel region 112 is reverse biased, blocking voltage and/or current.

Further consider, in the forward bias case, that a voltage is applied to the gate 154, and thus the gate region 120. When sufficient positive voltage is applied to the gate, a conductive channel forms in the conduction region between the substrate 106 and the cathode region 114. In the example of FIG. 1, an example conductive channel is shown as the area within the channel region 112 between the dashed line 158 and the insulator 122. The actual shape and extent of the conductive channel depends on several factors, such as doping of the channel region 112 and the voltage potential applied the gate. Moreover, conductive channel will not necessarily be a “straight” path through channel region 112. The conductive channel at least partially collapses the depletion region of the PN junction, and enables current to flow from the anode 150 to the cathode 152. The specification now turns to a set of example states of operation for the bipolar junction device 100.

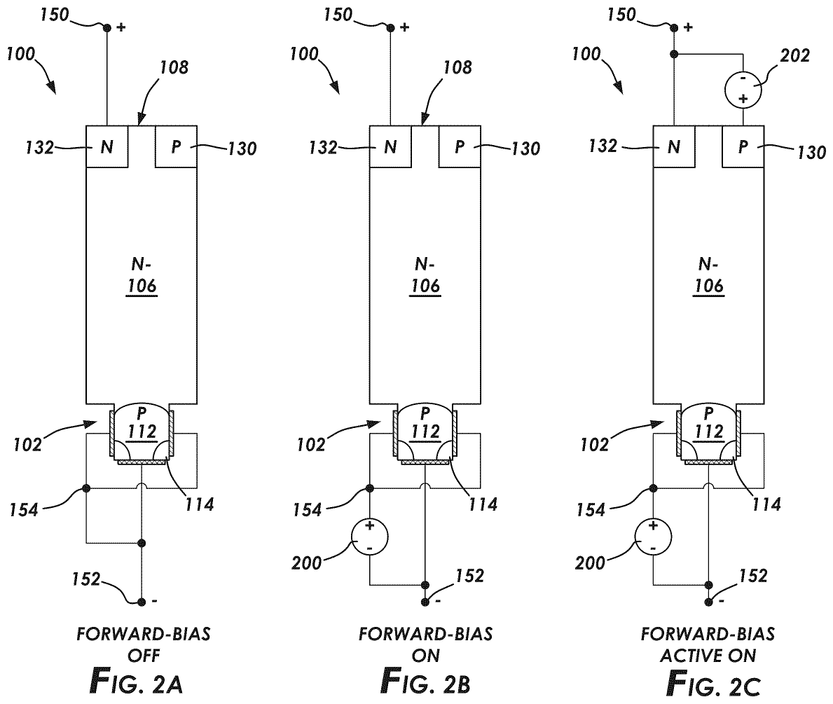

FIGS. 2A-2E show states of operation of the example bipolar junction device 100. Referring initially to FIG. 2A as representative, the example bipolar junction device 100 is shown in simplified form, with the bipolar junction structure 108 shown on the top of the drawing, and the field-effect structure 102 shown the bottom of the drawing, such that forward bias of the bipolar junction device 100 is shown with the positive voltage at the top of the figure. Shown with respect to the bipolar junction structure 108 are the injection region 130 and the anode region 132 coupled to the anode 150. Shown with respect to the field-effect structure 102 are the gate 154, the cathode 152, the channel region 112, and the cathode region 114.

FIG. 2A shows a forward-biased off arrangement of the bipolar junction device 100. In particular, in the example forward-bias off arrangement, the injection region 130 is electrically floated, while the gate 154 has a low or no voltage relative to the substrate 106. The low or no voltage condition of the gate 154 is illustrated in FIG. 2A by electrically shorting the gate to the anode 150. An equivalent arrangement may be to couple the gate to a body connection (e.g., to the substrate 106 near the junction with the channel region 112). In the example forward-biased off arrangement, the internal PN junction formed between the substrate 106 and the channel region 112 is reverse biased, and no conductive channel is formed in the channel region 112, and thus the bipolar junction device 100 blocks voltage and current.

FIG. 2B shows a forward-biased on arrangement of the bipolar junction device 100. In particular, in the example forward-biased on arrangement, the injection region 130 is electrically floated. A voltage source 200 is coupled between the gate 154 and the cathode 152, with the positive terminal coupled to the gate 154. The gate voltage applied by the voltage source 200 creates a conductive channel (not specifically shown) within the channel region 112. Thus, electrical current flows from the anode 150, to the anode region 132, through the substrate 106, through the conductive channel, through the cathode region 114, and then to the cathode 152. The voltage drop across the bipolar junction device 100 in the forward-biased on condition will be directly related to the thickness of the substrate 106. For a substrate 106 having a thickness of 160 microns, the inherent resistance is about 2 ohms. Thus, for a forward current of 30 A, the bipolar junction device 100 may have a voltage drop of about 60V. However, the voltage drop can be reduced.

FIG. 2C shows a forward-biased active on arrangement of the bipolar junction device 100. In particular, in the example forward-biased active on arrangement, again the voltage source 200 is coupled between the gate 154 and the cathode 152, with the positive terminal coupled to the gate 154. The gate voltage creates the conductive channel (not specifically shown) within the channel region 112. Another voltage source, voltage source 202, is coupled between the anode 150 and the injection region 130. The voltage applied to the injection region 130 injects additional charge carriers into the substrate 106. Thus again, electrical current flows from the anode 150, to the anode region 132, through the substrate 106, through the conductive channel, through the cathode region 114, and then to the cathode 152. Because of the injection of charge carriers through the injection region 130, the voltage drop across the bipolar junction device 100 will be lower than the product of the amplitude of the main load current and the substrate inherent resistance. In one example, the expected voltage drop may be between and including 0.8 and 1.4V for 30 A of main load current. The specification now turns to reverse-biased conditions of the bipolar junction device 100.

FIG. 2D shows a reverse-biased passive arrangement of the bipolar junction device 100. In particular, in the example reverse-biased passive arrangement, the injection region 130 is electrically floated. In some cases, the gate 154 may be electrically connected to the cathode 152 as shown; however, the gate 154 may also be electrically floated or coupled to a voltage source-neither alternative arrangement changes the operation in the reverse-biased passive arrangement. Electrical current flows from the cathode 152, through the channel region 112, through the substrate 106, and then to the anode 150. The voltage drop across the bipolar junction device 100 in the reverse-biased passive arrangement condition will be directly related to the thickness of the substrate 106 and the inherent resistance of the substrate (e.g., about 2 Ohms). Thus, for a reverse current of 30 A, the bipolar junction device 100 may have a voltage drop of about 60V. However, even in the reverse-bias condition, the voltage drop can be reduced.

FIG. 2E shows a reverse-biased active arrangement of the bipolar junction device 100. In particular, in the example reverse-biased active arrangement, the gate 154 may be electrically connected to the cathode 152 as shown; however, the gate 154 may also be electrically floated or coupled to a voltage source. Voltage source 202 is coupled between the anode 150 and the injection region 130. The voltage applied to the injection region 130 injects additional charge carriers into the substrate 106. Thus again, electrical current flows from the cathode 152, through the channel region 112, through the substrate 106, and then to the anode 150. Because of the injection of charge carriers through the injection region 130, the voltage drop across the bipolar junction device 100 will be lower than the product of the amplitude of the main load current and the substrate inherent resistance. In one example, the expected voltage drop may be between and including 0.8 and 1.4V for 30 A of reverse current.

Considering FIGS. 2A-2E, when the bipolar junction device 100 is forward biased (e.g., FIGS. 2A-2C), a forward current through the bipolar junction device 100 may be selectively controlled by control of the gate voltage applied to the gate 154. Moreover, during periods of time when forward current is flowing, the voltage drop across the bipolar junction device 100 may be lowered by injection of charge carriers into the substrate 106 by way of the injection region 130. When the bipolar junction device 100 is reverse biased (FIGS. 2D-2E), a reverse current non-selectively flows through the device. Moreover, during periods of time when the reverse current is flowing, the voltage drop across the bipolar junction device 100 may be lowered by injection of charge carriers into the substrate 106. The description now turns to an example switch assembly based on the bipolar junction device.

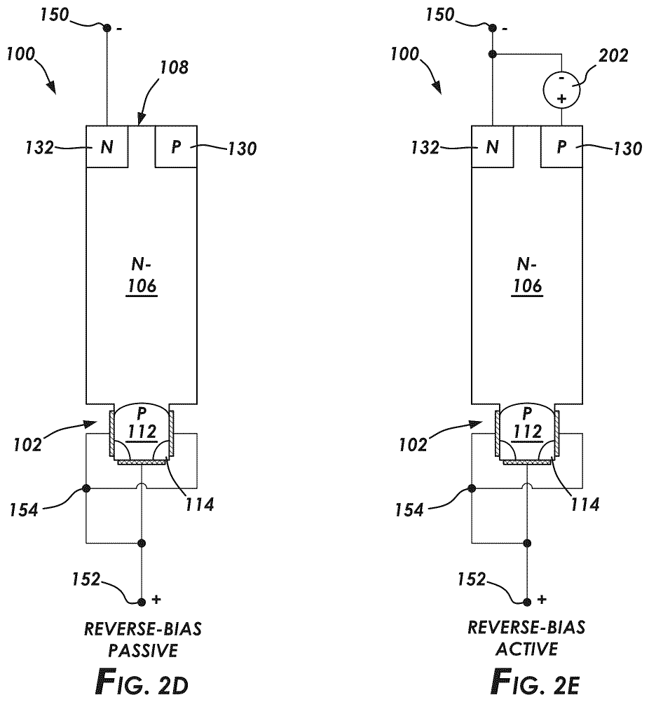

FIG. 3 shows, in block diagram form, an example switch assembly 300. In particular, the example switch assembly 300 defines an upper terminal 302, a lower terminal 304, and a control input or control terminal 306. Internally, the example switch assembly 300 includes a driver 308 and a bipolar junction device 100. The driver 308 defines the control terminal 306, and the driver 308 is coupled to the bipolar junction device 100, as shown by connections 312. As discussed in greater detail below, the connections 312, though shown as a single connection, represents a plurality of electrical connections to the bipolar junction device 100. The driver 308 controls the conductive state of the bipolar junction device 100 by arranging the conductive state, voltages, and/or currents on the connections 312.

One example of the switch assembly 300 may include a single bipolar junction device 100. Another example switch assembly 300 may have two or more bipolar junction devices 100, as illustrated in FIG. 3 by the “stacked” arrangement. When multiple bipolar junction devices 100 are present, the bipolar junction devices 100 are electrically connected in parallel to share the load current (forward or reverse). So as not to unduly complicate the specification, the discussion that follows assumes a single bipolar junction device 100. However, one having ordinary skill, with the benefit of this disclosure, understands that multiple bipolar junction devices 100 may be present depending on the designed current carrying capability of any specific switch assembly 300.

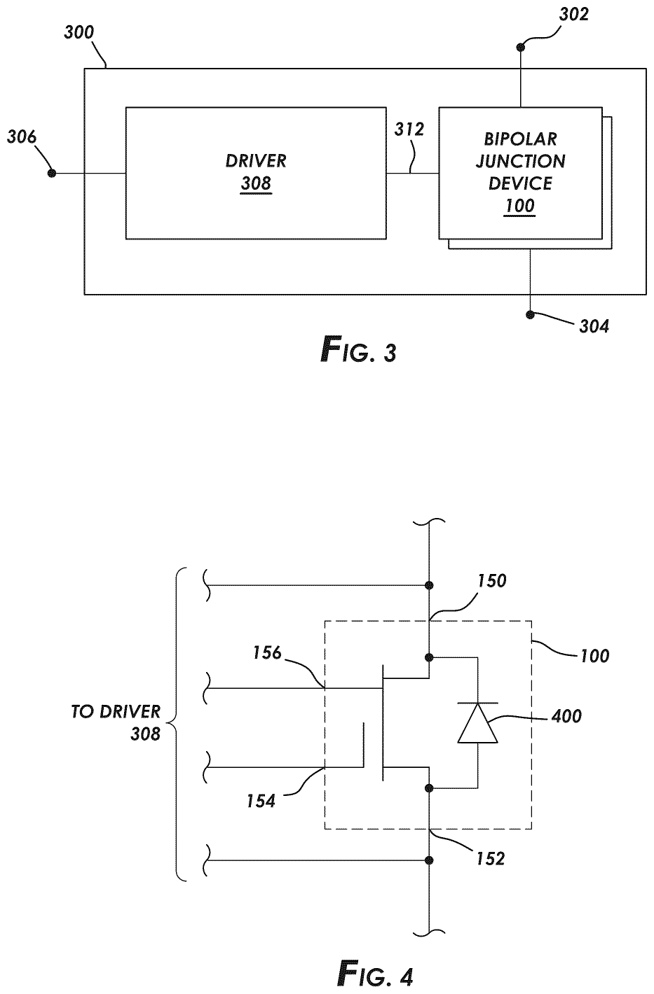

FIG. 4 shows an example circuit symbol for the bipolar junction device 100. The circuit symbol is coined herein and is akin to both the circuit symbol for a FET and the circuit symbol for a junction transistor. The circuit symbol for the bipolar junction device 100 defines the anode 150, the injection terminal 156, the gate 154, and the cathode 152. Also shown by the circuit symbol is a body diode 400 with the understanding that the diode functionality is implemented by the channel region 112 (FIG. 1) and substrate 106 (also FIG. 1). The driver 308 is coupled to the bipolar junction device 100 by a plurality of electrical connections. In the example of FIG. 4, the electrical connections to the driver 308 may comprise connections to: the anode 150, the injection terminal 156, the gate 154, and the cathode 152.

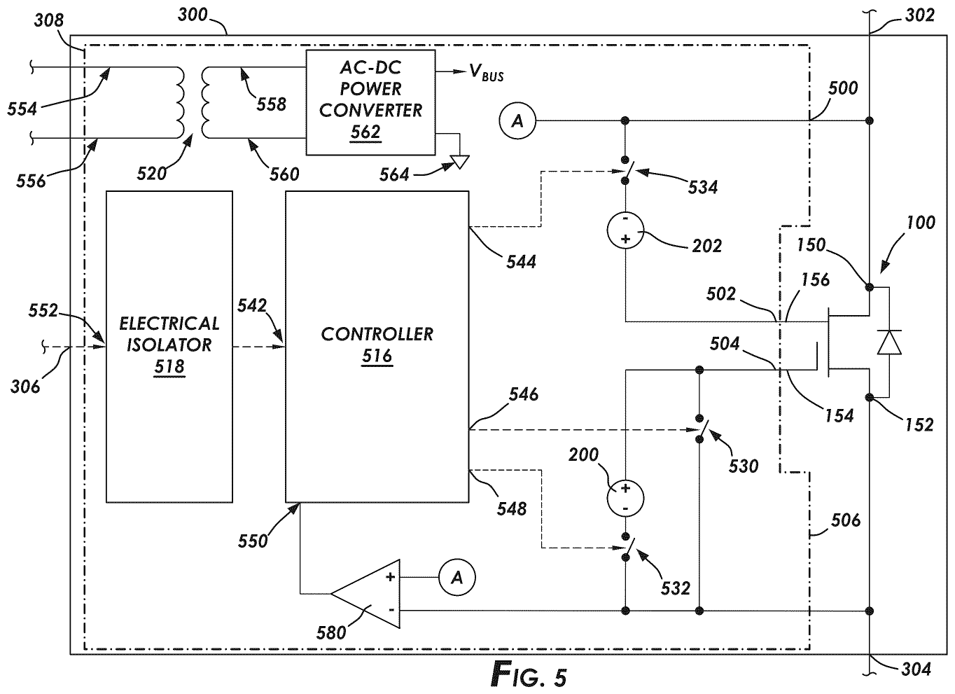

FIG. 5 shows a partial block diagram, partial electrical schematic, of an example switch assembly 300. In particular, the example switch assembly 300 comprises the example bipolar junction device 100 and the driver 308. The circuit symbol for the bipolar junction device 100 includes the anode 150 coupled to the upper terminal 302, the injection terminal 156, the gate 154, and the cathode 152 coupled to the lower terminal 304. The example driver 308 defines an upper sense terminal 500 coupled to the anode 150, an injection connection 502 coupled to the injection terminal 156, a gate terminal 504 coupled to the gate 154, and a lower sense terminal 506 coupled to the cathode 152.

The example driver 308 comprises a controller 516, an electrical isolator 518, and an isolation transformer 520. In order to place the bipolar junction device 100 in the various operational states of FIGS. 2A-2E, the example driver 308 includes a plurality of electrically-controlled switches and sources. In particular, the example driver 308 comprises an electrically-controlled switch 530 (hereafter just switch 530) that has a first lead coupled to the cathode 152, a second lead coupled to the gate 154, and a control input coupled to the controller 516. The example switch 530 is shown as a single-pole, single-throw switch, but in practice the switch 530 may be a FET with the control input being a gate of the FET. Thus, when the switch 530 is conductive based on assertion of its control input, the gate 154 is coupled to the cathode 152 (e.g., FIG. 2A or 2D-2E).

The driver 308 further comprises the source 200 having a positive lead coupled to the gate 154. Another electrically-controlled switch 532 (hereafter just switch 532) has a first lead coupled to the return or negative lead of the source 200, a second lead coupled to the cathode 152, and a control input coupled to the controller 516. The example switch 532 is shown as a single-pole, single-throw switch, but in practice, the switch 532 may be a FET with the control input being the gate of the FET. Thus, when the switch 532 is conductive, the source 200 is coupled between the cathode 152 and the gate 154 (e.g., FIG. 2B or 2C).

Still referring to FIG. 5, the driver 308 further comprises the source 202 having a positive lead coupled to the injection terminal 156. Another electrically-controlled switch 534 (hereafter just switch 534) has a first lead coupled to the return or negative lead of the source 202, a second lead coupled to the anode 150, and a control input coupled to the controller 516. The example switch 534 is shown as a single-pole, single-throw switch, but in practice, the switch 532 may be a FET with the control input being the gate of the FET. Thus, when the switch 534 is conductive, the source 200 is coupled between the anode 150 and the injection terminal 156 (e.g., FIG. 2C or 2E).

The controller 516 defines a control input 542, and control outputs 544, 546, and 548 coupled to the control inputs of the switches 534, 530, and 532, respectively. When the control input 542 is asserted, the controller 516 is designed and constructed to arrange the bipolar junction device 100 for conduction from the anode 150 to the cathode 152 (e.g., FIG. 2B or 2C). When the control input 542 is de-asserted, the controller 516 is designed and constructed to make the bipolar junction device 100 non-conductive (e.g., FIG. 2A). Stated otherwise, the controller 516 is configured to selectively arrange the bipolar junction device 100 for conduction when the switch assembly is forward biased.

Oppositely, independent of the state of the control input 542, when the switch assembly 300 is reverse biased, the controller 516 may take no action, as the reverse current will flow regardless of the state of the switches, owing to the built in “body diode” operation of the bipolar junction device 100. However, in some cases the controller 516, upon sensing reverse bias applied to the bipolar junction device 100, may arrange the bipolar junction device 100 into either the reverse-biased passive arrangement (e.g., FIG. 2D) or the reverse-biased active arrangement (e.g., FIG. 2E). Thus, in some cases, the controller 516 may further define a polarity input 550 that receives a Boolean indication of the applied polarity. In the example driver 308, a comparator 580 has a first input coupled to the anode 150 (the connection shown by bubble “A”) and a second input coupled to the cathode 152. The comparator 580 defines a compare output coupled to the polarity input 550. While FIG. 5 shows the first and second inputs coupled directly to the respective terminals, in practice the voltage across the bipolar junction device 100 when non-conductive may be large (e.g., 1200V) and thus each of the first and second inputs may be coupled to their respective conduction terminals by way of respective voltage divider circuits. In yet still further cases, the applied polarity may be determined by systems and devices external to the switch assembly 300, and a Boolean signal sent across the electrical isolator 518 to the polarity input 550.

The controller 516 may be individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations, configured to read the control input 542, read the polarity input 550 when implemented, and drive control outputs to implement the mode transitions of the bipolar junction device 100.

In example systems, the switch assembly 300 is electrically floated. In order to receive the control input 542 in the electrical domain of the switch assembly 300, the example driver 308 implements the electrical isolator 518. The example electrical isolator 518 may take any suitable form, such as optocouplers or capacitive isolation devices. Regardless of the precise nature of the electrical isolator 518, external control signals (e.g., Boolean signals) may be coupled to the control input 552 of the electrical isolator 518, and control input 552 may be the control terminal 306. The electrical isolator 518, in turn, passes the control signals through to the electrical domain of the switch assembly 300. In the example, the external control signal is passed through to become the control input 542 of the controller 516.

Turning now to the isolation transformer 520, various devices within the switch assembly 300 may use operational power. For example, the controller 516 may use a bus voltage and power to enable implementation of the various modes of operation of the bipolar junction device 100. Further, the sources 200 and 202 may be implemented in the form of switching power converters, or current sources also in the form of switching power converters. The switching power converters implementing the sources may use bus voltage and power. In order to provide operational power within the electrical domain of the switch assembly 300, the isolation transformer 520 is provided. External systems (not specifically shown) may provide an alternating current (AC) signal across the primary leads 554 and 556 of the isolation transformer 520 (e.g., 15V AC). The isolation transformer 520 creates an AC voltage on the secondary leads 558 and 560. The AC voltage on the secondary of the isolation transformer 520 may be provided to an AC-DC power converter 562, which rectifies the AC voltage and provides power by way of bus voltage V_{BUS} (e.g., 3.3V, 5V, 12V) with respect to a reference voltage or common 564. The power provided by the AC-DC power converter 562 may be used by the various components of the switch assembly 300. In other cases, multiple isolation transformers may be present (e.g., one for each side of the bipolar junction device). Further still, a single isolation transformer with multiple secondary windings may be used.

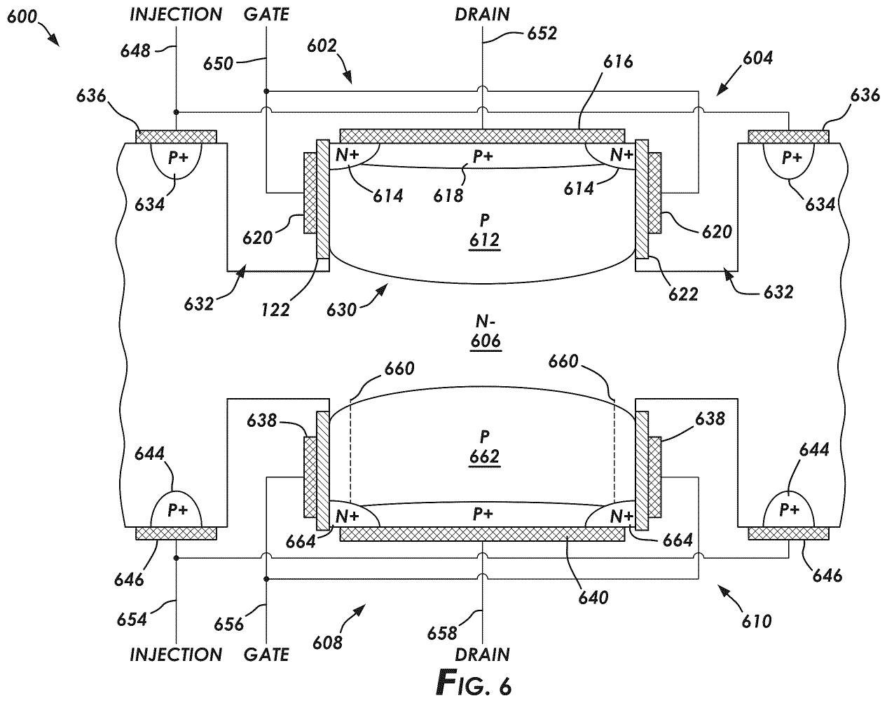

FIGS. 6-12 are generally directed to a semiconductor device that is bidirectional, and switch assemblies using such a semiconductor device. FIG. 6 shows a partial cross-sectional view of an example semiconductor device 600. In particular, FIG. 6 shows a cross-sectional view of a cell of the semiconductor device 600 comprising an upper field-effect transistor 602 on an upper side 604 of a substrate 606, and a lower field-effect transistor 608 on a lower side 610 of the substrate 606. The terms “upper” and “lower” are relational terms, which may be derived from the position of the structures and/or regions in the example figure. The terms “upper” and “lower” shall not be read to imply any location with respect to gravity. While only a single upper field-effect transistor 608 is shown, and only a single lower field-effect transistor 608 is shown, the upper side and lower side may each have many such duplicative field-effect transistors.

Referring initially to the upper side 604, the example field-effect transistor 602 comprises a channel region 612 (e.g., a P-type region). As will be discussed in greater detail below, it is within the channel region 612 that a conductive channel is formed during periods of time when the field-effect transistor 602 is used to selectively flow forward current through the semiconductor device 600. The upper field-effect transistor 602 further comprises a drain region 614 (e.g., N+) forming a junction with the channel region 612. FIG. 6, being a cross-sectional view, shows two instances of the drain region 614 owing to the cell structure of the device. That is, in some cases, the drain region 614 is a continuous region (e.g., circular, obround, or “U” shaped), and the cross-sectional view of FIG. 6 happens to show both sides of the continuous drain region 614. In other cases, however, the drain regions may be separate and distinct from each other.

The example drain region 614 is electrically coupled to a drain metal 616. In particular, the drain metal 616 may be deposited on the upper side 604 at any suitable time during construction of the semiconductor device 600. In example cases, the drain metal 616 forms an ohmic contact (e.g., non-rectifying contact) to or with the drain region 614. Additional layers, including additional metal layers (e.g., titanium), may be present to form the ohmic contact, but those additional layers are not shown so as not to unduly complicate the figure.

Disposed in the region between the instances of the drain region 614 is an example P-type region 618 (e.g., P+). The example drain metal 616 may likewise be in electrical contact with the P-type region 618. In most cases, the electrical contact between the drain metal 616 and the P-type region 618 is also an ohmic connection; however, a non-ohmic or rectifying (e.g., Schottky) connection is also contemplated, as such a rectifying connection will be forward biased during reverse current flow.

The upper field-effect transistor 602 further comprises a gate structure 620 in operational relationship to the channel region 612, and the gate structure 620 is electrically isolated from the channel region 612. The cross-sectional view of FIG. 6 shows two instances of the gate structure 620 owing to the cell structure of the device. That is, in some cases, the gate structure 620 is a continuous structure (e.g., circular, obround, or “U” shaped), and the cross-sectional view of FIG. 6 happens to show both sides of the continuous gate structure 620. In other cases, however, the gate structures may be separate and distinct, but nevertheless electrically connected in operation. In some examples, the gate structure 620 may be a metallic material, but in other cases the gate structure(s) may be polysilicon with high conductivity. An insulator 622 (e.g., oxide) may electrically isolate the gate structure 620 from the drain region 614, such as an oxide layer having a thickness of about 0.5 microns.

Still referring to FIG. 6, the example upper field-effect transistor 602 is constructed on or associated with a ridge 630 defined on the substrate 606. In particular, the upper side 604 defines a trench region 632. The cross-sectional view of FIG. 6 shows two instances of the trench region 632 owing to the cell structure of the device. That is, in some cases, the trench region 632 is a continuous structure (e.g., circular, obround, or “U” shaped), and the cross-sectional view of FIG. 6 happens to show both sides of a continuous trench. In other cases, however, the trench regions may be separate and distinct trenches. The ridge 630 defines a first sidewall associated with the trench region 632 on the left, a second sidewall associated with the trench region 632 on the right, and an upper crest upon which the drain metal 616 is perched.

The upper side 604 further comprises an injection region 634 defined within the substrate 606 (e.g., a doped region), and an associated injection metal 636 electrically coupled to the injection region 634. The cross-sectional view of FIG. 6 shows two instances of the injection region 634 and injection metal 636 owing to the cell structure of the device. That is, in some cases, the injection region 634 and injection metal 636 are continuous structures (e.g., circular, obround, or “U” shaped), and the cross-sectional view of FIG. 6 happens to show both sides of the continuous structures. In other cases, however, the injection regions and respective injection metals may be separate and distinct structures, but nevertheless electrically connected in operation. In the example of FIG. 6, the injection region 634 is a P-type region (e.g., P+) implanted though the upper surface 604, and thus forms a junction with the N-type substrate 606. In most cases, the electrical contact between the injection region 634 and the injection metal 636 is an ohmic connection; however, a non-ohmic or rectifying (e.g., Schottky) connection is also contemplated.

Still referring to FIG. 6, and turning now to the lower side 610, the lower side 610 comprises the lower field-effect transistor 608 comprising a gate structure 638, drain metal 640, and the internal structures, such as the channel region 662. Moreover, the lower side 610 has an injection region 644 and an injection metal 646. In various examples, the regions and structures of the lower side 610 are a mirror image of the regions and structures on the upper side, though the regions and structures may be constructed at different times. A description of the regions and structures on the lower side 610 is duplicative of description of the upper side 604, and thus such is not repeated again so as not to unduly lengthen the specification.

The semiconductor device 600 may be packaged into a packaged semiconductor product. In the packaged product, the various electrical connections may be accessible by way of pins or terminals on an exterior surface of the packaging. For example, regarding the upper side 604: the injection metal 636 may be coupled to an upper injection terminal 648; the gate structure 620 may be coupled to an upper gate terminal 650; and the drain metal 616 may be coupled to an upper drain terminal 652. Similarly regarding the lower side 610: the injection metal 646 may be coupled to a lower injection terminal 654; the gate structure 638 may be coupled to a lower gate terminal 656; and the drain metal 640 may be coupled to a lower drain terminal 658. Thus, the packaged product may have six separate and distinct externally accessible terminals. In other cases, the upper and lower injection regions may be electrically coupled together within the packaging, and thus a single injection terminal may be used.

The specification now turns to a description of operation of the example semiconductor device 600. Consider that an external voltage is applied to the semiconductor device 600, with the upper drain terminal 652 having a higher voltage relative to the lower drain terminal 658, the arrangement hereafter just “forward bias” or “forward biased.” In the absence of a voltage on the lower gate terminal 656, the semiconductor device 600 blocks current flow. In particular, while the internal PN junction formed between the upper channel region 612 and the substrate 606 is forward biased, the internal PN junction formed between the lower channel region 662 and the substrate 606 is reverse biased, blocking current.

Still with forward bias, now consider that a voltage is applied to the lower gate terminal 656. When sufficient positive voltage is applied to the lower gate terminal 656, a conductive channel forms in the channel region 662 between the substrate 606 and the drain region 614. In the example of FIG. 6, an example conductive channel is shown as the volume within the channel region 662 between the dashed line 660 and the insulator for the gate region structure 638. The actual shape and extent of the conductive channel depends on several factors, such as doping of the channel region 662 and the voltage potential applied the gate. Moreover, the conductive channel will not necessarily be a “straight” path through channel region 662. The conductive channel is formed by the voltage applied to the lower gate terminal 656 and the gate structure 638 at least partially collapses the depletion region of the PN junction between the P-type channel region 662 and the N-type substrate 606.

Speaking in terms of traditional electrical current, the conductive channel enables current to flow from the drain metal 616, then through the drain region 614, then through the channel region 612, then through a drift region within the substrate 606 between channel region 612, then through the conductive channel within the channel region 662 of the lower field-effect transistor 608, and then out through the drain metal 640. Spoken of in terms of device physics, electrons flow from the drain metal 640, through the conductive within the channel region 662, then through the substrate 606, then through the channel region 612, then through drain region 614, and then to the drain metal 616.

One of the parameters designers use to gauge or rate power semiconductor devices is the voltage drop across the device during the fully conductive state—the V_{DDON}. In some cases, the semiconductor device 600 may have a thickness of between about 160 microns and 280 microns. For a thickness of about 160 microns, the inherent substrate resistance may be about 2 Ohms. Thus, for an example 30 Amps (A) of main load current, the example semiconductor device may cause a voltage drop V_{DDON} of about 60V measured from the upper drain terminal 652 to the lower drain terminal 658. However, the voltage drop may be reduced.

In accordance with various examples, during periods of time when the semiconductor device 600 is forward biased and conducting main load current, the V_{DDON} may be reduced by injection of charge carriers into the drift region of the substrate 606 using the injection regions. In the forward biased condition, a positive voltage (e.g., 0.1 to 3.0V) may be applied to upper injection terminal 648. The positive voltage injects charge carriers from the injection region 634 into the drift region of the substrate 606. More particularly, with the applied voltage the injection region 634 injects minority charge carriers, here holes, into the drift region. The minority charge carriers attract electrons transitioning through the substrate, increasing electron mobility and thus decreasing voltage drop. In other cases, the voltage drop V_{DDON} may be reduced by injection charge carriers through the injection region 644 of the lower side 610. In yet still other cases, voltage drop V_{DDON} may be reduced by injection of charge carriers from both injection regions 634 and 644.

Now consider that an external voltage is applied to the semiconductor device 600, with the lower drain terminal 658 having a higher voltage relative to the upper drain terminal 652, the arrangement hereafter just “reverse bias” or “reverse biased.” In the absence of a voltage on the lower gate terminal 656, the semiconductor device 600 blocks current flow. In particular, the internal PN junction formed between the upper channel region 612 and the substrate 606 is reverse biased, blocking current. However, when sufficient positive voltage is applied to the upper gate terminal 650, a conductive channel forms in the channel region 612 between the substrate 606 and the drain region 614, enabling current to flow from the lower drain terminal 658 to the upper drain terminal 652.

During periods of time when the semiconductor device 600 is reverse biased and conducting main load current, the V_{DDON} may be reduced by injection of charge carriers into the drift region of the substrate 606 using the injection regions. In the reverse biased condition, a positive voltage (e.g., 0.1 to 3.0V) may be applied to lower injection terminal 654. The positive voltage injects charge carriers from the injection region 644 into the drift region of the substrate 606. In other cases, the voltage drop V_{DDON} during reverse bias may be reduced by injection of charge carriers through the injection region 634 of the upper side 604. In yet still other cases, voltage drop V_{DDON} during reverse bias may be reduced by injection of charge carriers from both injection regions 634 and 644.

In the example of FIG. 6, the injection regions are formed in and on ridges interdigitated with ridges forming the field-effect transistors. Other arrangements are possible, and the specification now turns to several example arrangements.

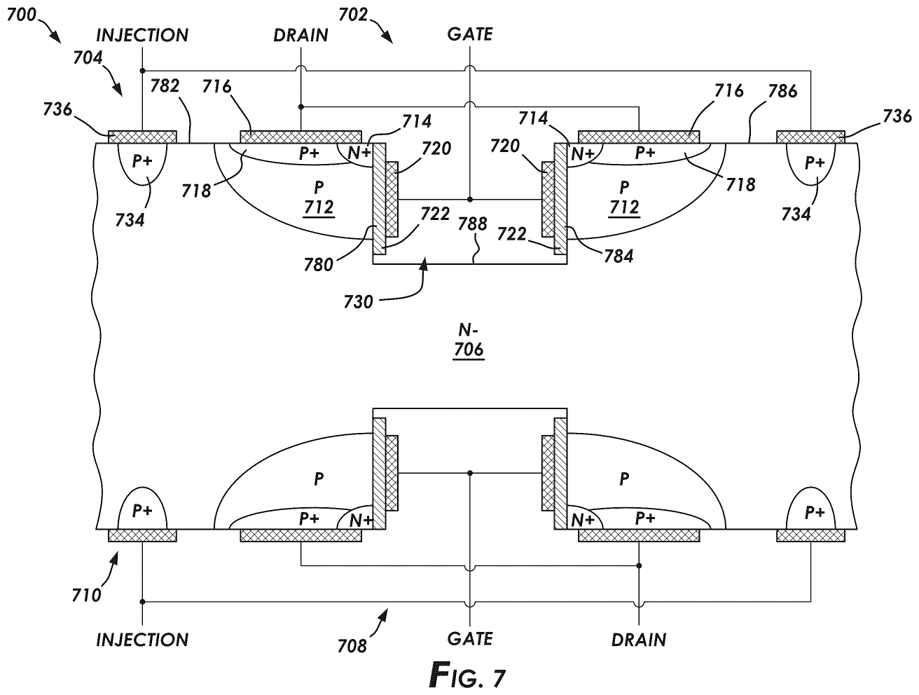

FIG. 7 shows a partial cross-sectional view of another example semiconductor device 700. In particular, FIG. 7 shows a cross-sectional view of a cell of the semiconductor device 700 comprising an upper field-effect transistor 702 on an upper side 704 of a substrate 706, and a lower field-effect transistor 708 on a lower side 710 of the substrate 706. The upper side and lower side may each have many such duplicative field-effect transistors depending on the designed current carrying capacity of the device.

The example field-effect transistor 702 comprises a channel region 712 (e.g., a P-type region). As discussed with respect to other components, the channel region 712 may be a continuous region or distinct regions. The upper field-effect transistor 702 further comprises a drain region 714 (e.g., N+) forming a junction with the channel region 712. As discussed with respect to other components, the drain region 714 may be a continuous region or distinct regions. The example drain region 714 is electrically coupled to a drain metal 716, which may be a continuous structure or distinct structures. The example drain metal 716 may be deposited on the upper side 704 at any suitable time during construction of the semiconductor device 700. In example cases, the drain metal 716 forms an ohmic contact (e.g., non-rectifying contact) to or with the drain region 714.

Also included is an example P-type region 718 (e.g., P+), which may be continuous region or distinct regions. The example drain metal 716 may likewise be in electrical contact with the P-type region 718. In most cases, the electrical contact between the drain metal 716 and the P-type region 718 is also an ohmic connection; however, a non-ohmic or rectifying connection is also contemplated.

The upper field-effect transistor 702 further comprises a gate structure 720 in operational relationship to the channel region 712, and the gate structure 720 is electrically isolated from the channel region 712. As discussed with respect to other components, the gate structure 720 may be a continuous structure or distinct structures. In some examples, the gate structure 720 may be a metallic material, but in other cases the gate structure may be polysilicon with high conductivity. An insulator 722 (e.g., oxide) may electrically isolate the gate structure 720 from the drain region 714.

Still referring to FIG. 7, the example upper field-effect transistor 702 is associated with trench 730 defined within the substrate 706, the trench 730 thus defines: a first sidewall 780 and associated with a first bench or first terrace 782; a second sidewall 784 associated with a second bench or second terrace 786; and a bottom 788. In the example of FIG. 7, a portion of the gate structure 720 is associated with the first sidewall 780, and a portion of the gate structure 720 is associated with the second sidewall 784. Stated otherwise, the example gate structure(s) 720, and associated insulator(s) 722, reside within trench 730.

The upper side 704 further comprises an injection region 734 defined on the terraces 782/786 within the substrate 706, and an associated injection metal 736 electrically coupled to the injection region 734. As discussed with respect to other components, the injection region 734 and injection metal 736 may each be a continuous structure or distinct structures. In the example of FIG. 7, the injection region 734 is a P-type region (e.g., P+).

Still referring to FIG. 7, and turning now to the lower side 710, the lower side 710 comprises the lower field-effect transistor 708. The regions and structures of the lower side 710 are a mirror image of the regions and structures on the upper side 704, though the regions and structures may be constructed at different times. A description of the regions and structures on the lower side 710 is duplicative of the description above, and is not repeated again so as not to unduly lengthen the specification.

Thus, FIG. 7 shows an arrangement in which both sidewalls of a trench may be associated with a gate structure. Moreover, FIG. 7 shows an arrangement in which the injection regions (e.g., injection region 734) need not be disposed on a dedicate ridge; rather, the injection regions may be on the terraces co-located with the field-effect regions (e.g., channel region 712). In a packaged product, the various regions and structures of the semiconductor device 700 couple to external pins or terminals, thus defining for each side an injection terminal, a drain terminal, and a gate terminal, though the terminals are not specifically numbered in FIG. 7. Moreover, operation of the semiconductor device 700 of FIG. 7 with forward and reverse bias is similar to the operation of semiconductor device 600 of FIG. 6, and the operation will not be repeated again here so as not to unduly lengthen the description.

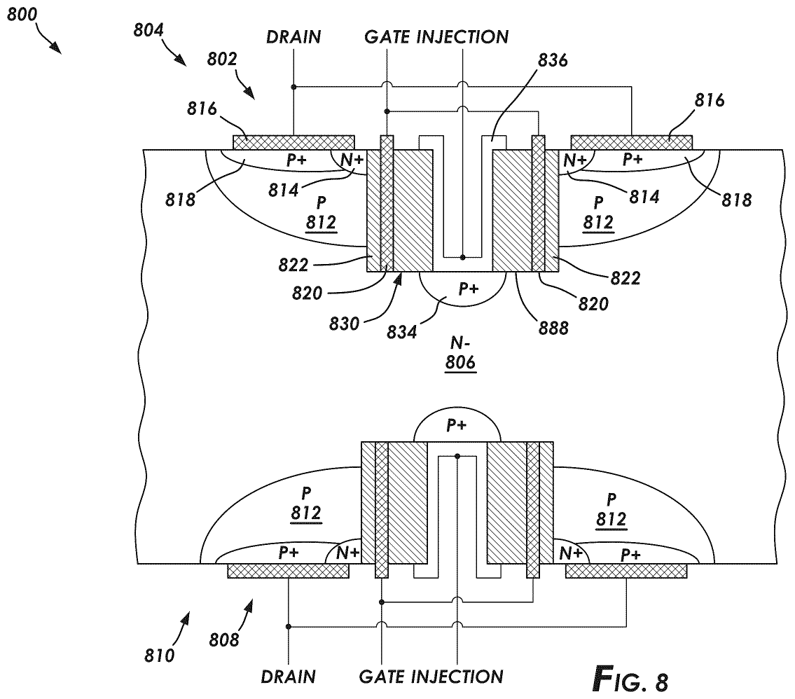

FIG. 8 shows a partial cross-sectional view of another example semiconductor device 800. In particular, FIG. 8 shows a cross-sectional view of a cell of the semiconductor device 800 comprising an upper field-effect transistor 802 on an upper side 804 of a substrate 806, and a lower field-effect transistor 808 on a lower side 810 of the substrate 806. The upper side and lower side may each have many such duplicative field-effect transistors depending on the designed current carrying capacity of the device.

The example field-effect transistor 802 comprises a channel region 812 (e.g., a P-type region). As discussed with respect to other components, the channel region 812 may be a continuous region or distinct regions. The upper field-effect transistor 802 further comprises a drain region 814 (e.g., N+) forming a junction with the channel region 812. The drain region 814 may be a continuous region or distinct regions. The example drain region 114 is electrically coupled to a drain metal 816, which may be a continuous structure or distinct structures. The example drain metal 816 may be deposited on the upper side 804 at any suitable time during construction of the semiconductor device 800. In example cases, the drain metal 816 forms an ohmic contact (e.g., non-rectifying contact) to or with the drain region 814.

Also included is an example P-type region 818 (e.g., P+), which may be a continuous region or distinct regions. The example drain metal 816 may likewise be in electrical contact with the P-type region 818. In most cases, the electrical contact between the drain metal 816 and the P-type region 818 is an ohmic connection.

The upper field-effect transistor 802 further comprises a gate structure 820 in operational relationship to the channel region 812, and the gate structure 820 is electrically isolated from the channel region 812. The gate structure 820 may be a continuous structure or distinct structures. In some examples, the gate structure 820 may be a metallic material, but in other cases the gate structure may be polysilicon with high conductivity. An insulator 822 (e.g., oxide) may electrically isolate the gate structure 820 from the drain region 814.

Still referring to FIG. 8, the example upper field-effect transistor 802 is associated with a trench 830 defining a first sidewall associated with a left bench or left terrace, a second sidewall associated with a right bench or right terrace, and a bottom 888. In the example of FIG. 8, a portion of the gate structure 220 is associated with the left sidewall, and a portion of the gate structure 820 is associated with the right sidewall. Stated otherwise, the gate structure(s) 820, and associated insulator(s) 822, reside within trench 830. The upper side 804 further comprises an injection region 834 defined on the bottom 888 of the trench 830 within substrate 206, and an associated injection metal 836 electrically coupled to the injection region 834. In the example of FIG. 8, the injection region 834 is a P-type region (e.g., P+).

Still referring to FIG. 8, and turning now to the lower side 810, the lower side 810 comprises the lower field-effect transistor 808. The regions and structures of the lower side 810 are a mirror image of the regions and structures on the upper side, though the regions and structures may be constructed at different times. A description of the regions and structures on the lower side 810 is duplicative of description above, and such is not repeated again so as not to unduly lengthen the specification.

Thus, FIG. 8 shows an arrangement in which both sidewalls of a trench may be associated with a gate structure, whether continuous or discrete. Moreover, FIG. 8 shows an arrangement in which the injection region (e.g., injection region 834) is disposed at the bottom 888 of the trench 830 (e.g., trench tip implant). Having the injection region 834 at the bottom of the trench makes the carrier injection closer to the drift region defined in the substrate 806 between the upper and lower field-effect transistors, thus making the carrier injection more efficient. In a packaged product, the various regions and structures of the semiconductor device 800 couple to external pins or terminals, thus defining for each side an injection terminal, a drain terminal, and a gate terminal, though the terminals are (not specifically numbered in FIG. 8). Moreover, operation of the semiconductor device 800 of FIG. 8 with forward and reverse bias is similar to the operation of semiconductor device 600 of FIG. 6, and thus the operation will not be repeated again here so as not to unduly lengthen the description.

Understanding operation of the device and having learned various example layouts, one having ordinary skill in the art could envision further arrangements. For example, another arrangement is having, within each trench, a single gate structure and an injection region. The injection region could be associated with the bottom of the trench, the sidewall opposite the gate structure, or combinations.

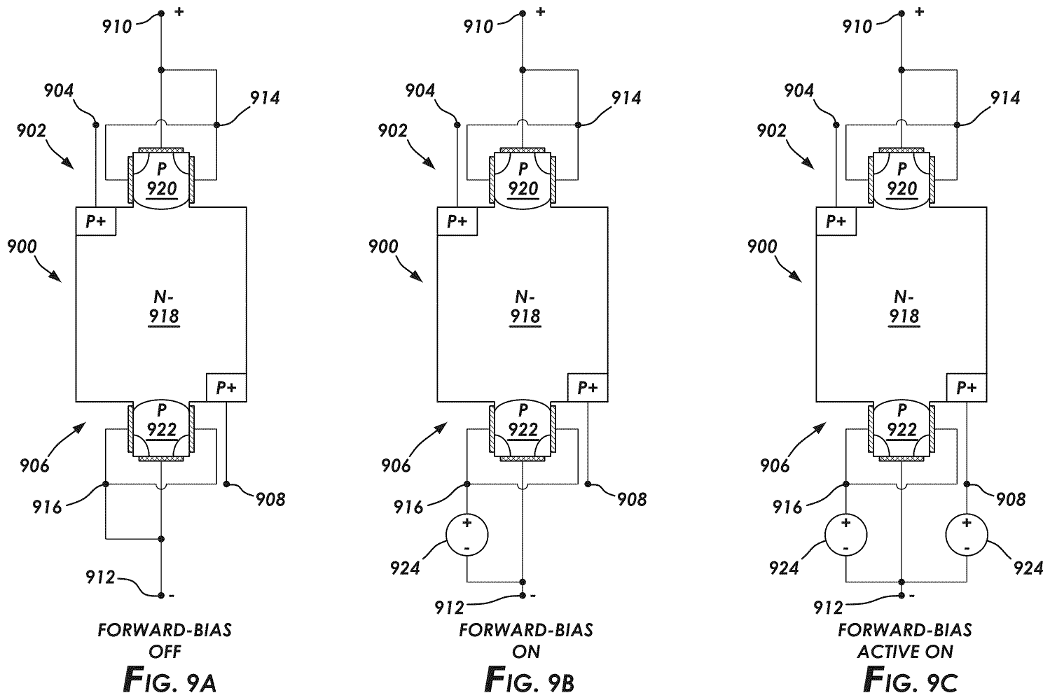

FIGS. 9A-9E show states of operation of an example semiconductor device 900. Semiconductor device 900 is representative of any of the semiconductor devices 600, 700, and/or 800. Referring initially to FIG. 9A, the example semiconductor device 900 is shown in simplified form, with an upper field-effect transistor 902, an associated upper injection region, a lower field-effect transistor 906, and an associated lower injection region. The semiconductor device defines an upper drain terminal 910 coupled to the upper drain metal and a lower drain terminal 912 coupled to the drain metal. The semiconductor device 900 further defines an upper gate terminal 914 coupled to the upper gate metal and a lower gate terminal 916 coupled to the lower gate metal. The semiconductor device 900 further defines an upper injection terminal 904 coupled to the upper injection region and a lower injection terminal 908 coupled the lower injection region. In the example arrangement of FIG. 9A, a voltage is applied to the semiconductor device 900, with the upper drain terminal 910 having a higher voltage relative to the lower drain terminal 912.

FIG. 9A shows a forward-bias off arrangement of the semiconductor device 900. In particular, in the example forward-bias off arrangement, the injection terminals 904 and 908 are electrically floated, while the upper gate terminal 914 has low or no voltage relative to upper drain terminal 910. The low or no voltage condition of the upper gate terminal 914 is illustrated in FIG. 9A by electrically shorting the upper gate terminal 914 to the upper drain terminal 910, but electrically floating the upper gate terminal 914 may have the same effect. In the example forward-bias off arrangement, the internal PN junction formed between the channel region 922 and the substrate 918 is reverse biased and no conductive channel is formed in the channel region 922 when the lower gate terminal 916 is floating or has zero volts. Thus, the semiconductor device 900 blocks voltage and current.

In the example forward-bias off arrangement of FIG. 9A, the upper field-effect transistor 902 is illustratively shown to have low or no voltage relative to upper drain terminal 910; however, even if a conductive channel is formed in the upper channel region 920 (e.g., the upper gate terminal 914 has a voltage applied), the overall semiconductor device 900 would still be non-conductive. Thus, the conductive state of the upper field-effect transistor 902 is a “don't care” condition in the example forward-bias off arrangement.

FIG. 9B shows a forward-bias on arrangement of the semiconductor device 900. In particular, in the example forward-biased on arrangement, the injection terminals 904 and 908 are electrically floated. A voltage source 924 is coupled between the lower drain terminal 912 and the lower gate terminal 916, with the positive terminal coupled to the lower gate terminal 916. The gate voltage applied by the voltage source 924 creates a conductive channel (not specifically shown) within the channel region 922. Thus, electrical current flows through the upper channel regions 920, through the substrate 918, through lower field-effect transistor 906, and then to the lower drain terminal 912.

In the forward-bias on arrangement with the lower field-effect transistor 906 conductive, the PN junction formed between the upper channel region 920 and the substrate 918 is forward biased and thus conductive. The presence or absence of a gate voltage on the upper gate terminal 914 does not substantively affect the conductivity through the upper channel region 920, and thus the voltage state of the upper gate terminal 914 is a “don't care” condition. In the example forward-bias on arrangement of FIG. 9B, the upper field-effect transistor 902 is illustratively shown to have low or no voltage relative to upper drain terminal 910.

The voltage drop across the semiconductor device 900 in the forward-bias on arrangement is directly related to the thickness of the substrate 918. For a substrate 918 having a thickness of 160 microns, the inherent resistance is about 2 ohms. Thus, for a forward current of 30 A, the semiconductor device 600 may have a voltage drop of about 60V. However, the voltage drop can be reduced.

FIG. 9C shows a forward-bias active-on arrangement of the semiconductor device 900. In particular, in the example forward-biased active-on arrangement, the voltage source 924 is coupled between the lower drain terminal 912 and the lower gate terminal 916, with the positive terminal coupled to the lower gate terminal 916. The gate voltage creates the conductive channel (not specifically shown) within the channel region 922. Another voltage source, voltage source 926, is coupled between the lower drain terminal 912 and the lower injection terminal 908, with the positive lead coupled to the lower injection terminal 904. The voltage applied to the lower injection terminal 908 injects charge carriers into the substrate 918. Thus again, electrical current flows from the upper channel region 920, through the substrate 918, through the lower field-effect transistor 906, and then to the lower drain terminal 912. The charge carriers (e.g., holes) injected by way of the lower injection terminal 908 lower the voltage drop in the drift region between the upper channel region 920 and the lower channel region 922, thus lowering the voltage drop across the semiconductor device 900. That is, considering the injection of charge carriers, the voltage drop across the semiconductor device 900 will be lower than the product of the amplitude of the main load current and the substrate inherent resistance. In one example, the expected voltage drop may be between and including 0.8 and 1.4V for 30 A of main load current.

FIG. 9D shows another forward-bias active-on arrangement of the semiconductor device 900. In particular, in the example forward-bias active-on arrangement, the voltage source 924 is coupled between the lower drain terminal 912 and the lower gate terminal 916. The gate voltage creates the conductive channel (not specifically shown) within the channel region 922. Voltage source 926 is coupled between the lower drain terminal 912 and the lower injection terminal 908. The voltage applied to the lower injection terminal 908 injects additional charge carriers into the substrate 918. Another voltage source 928 is coupled between the upper drain terminal 910 and the upper injection terminal 904, with the positive lead coupled to the upper injection terminal 904. The voltage applied to the upper injection region 904 also injects charge carriers into the substrate 918. Injecting charge carriers from both sides of the substrate 918 may further increase electron mobility, and thus further reduce the voltage drop across the semiconductor device 900.

FIG. 9E shows another forward-bias active-on arrangement of the semiconductor device 900. In particular, in the example forward-bias active-on arrangement, the voltage source 924 is coupled between the lower drain terminal 912 and the lower gate terminal 916. The lower injection terminal 908 is electrically floated. Voltage source 928 is coupled between the upper drain terminal 912 and the upper injection terminal 904. The voltage applied to the upper injection terminal 904 injects charge carriers into the substrate 918. In the forward-bias active-on arraignment, injecting charge carriers from only the upper injection region 908 may be just as efficient as only injecting charge carriers from the lower injection region 904 (i.e., FIG. 9C). There may be advantages in terms of driver design for such an arrangement.

The example semiconductor device 900 is a symmetrical device. Now understanding the how to operate the semiconductor device 900 in the forward bias condition, operating the device in the reversed biased condition is a duplicative description. So as not to unduly lengthen the specification, a full description for reverse biased operation thus omitted.

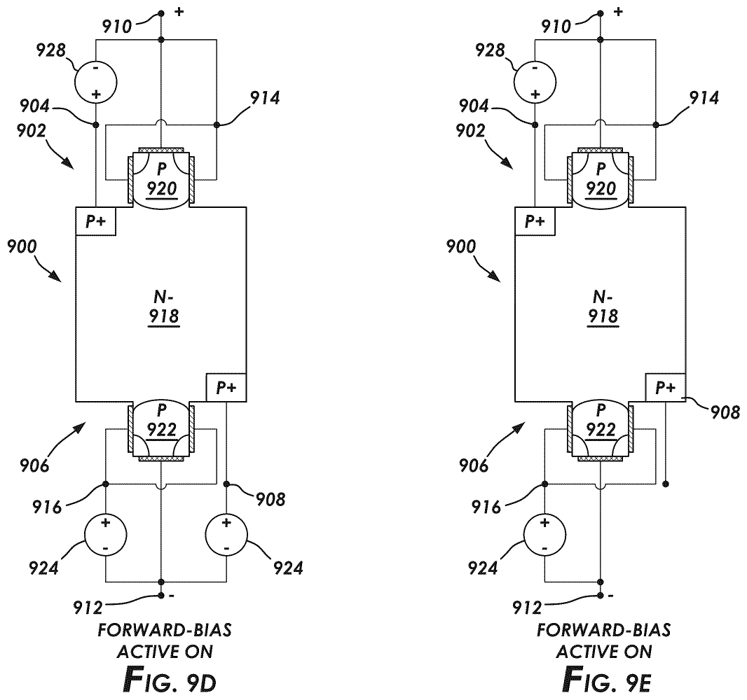

FIG. 10 shows, in block diagram form, an example switch assembly 1000. In particular, the example switch assembly 1000 defines an upper terminal 1002, a lower terminal 1004, a first control input or first control terminal 1006, and a second control input or second control terminal 1008. Internally, the example switch assembly 1000 includes a driver 1010 and a semiconductor device 900, again with semiconductor device 900 representative of any of the previously discussed semiconductor devices. The driver 1010 defines the control terminals 1006 and 1008, and the driver 1010 is coupled to the semiconductor device 900 by way of connections 1012. As discussed in greater detail below, the connections 1012, though shown as a single connection, represents a plurality of electrical connections to the semiconductor device 900. The driver 1010 controls the conductive state of the semiconductor device 900 by arranging the conductive state, voltages, and/or currents on the connections 1012.

One example of the switch assembly 1000 may include a single semiconductor device 900. Another example switch assembly 1000 may have two or more semiconductor devices 900, as illustrated in FIG. 10 by the “stacked” arrangement. When multiple semiconductor devices 900 are present, the semiconductor devices 900 are electrically connected in parallel to share the load current (forward or reverse). So as not to unduly complicate the specification, the discussion that follows assumes a single semiconductor device 900. However, one having ordinary skill, with the benefit of this disclosure, understands that multiple semiconductor devices 900 may be present depending on the designed current carrying capability of any specific switch assembly 1000.

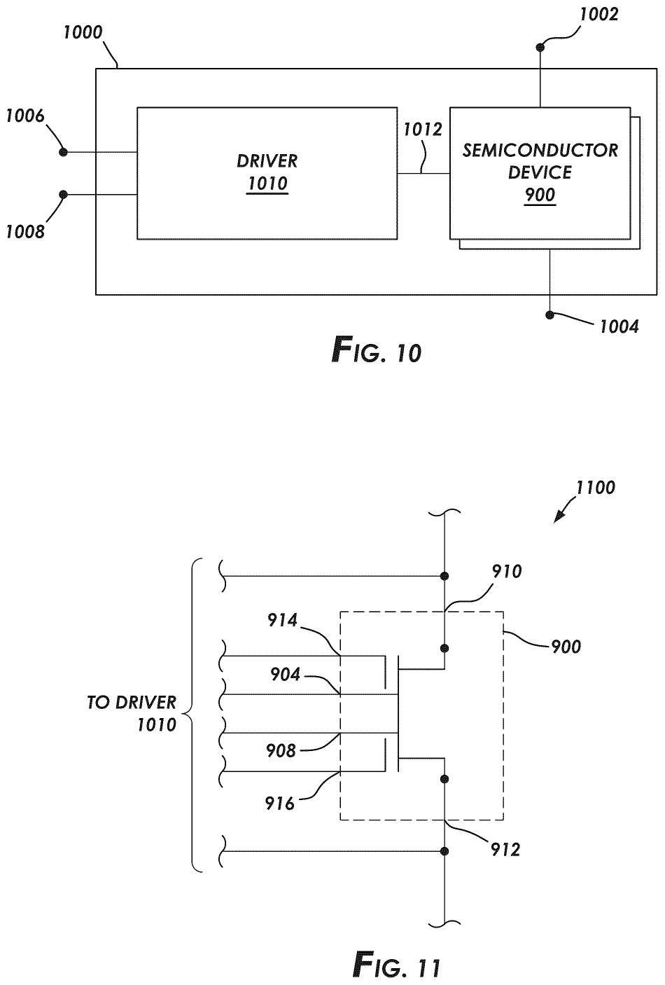

FIG. 11 shows an example circuit representation or symbol 1100 (e.g., a symbol representation) for the semiconductor device 900. The circuit symbol 1100 is coined herein and is akin to both the circuit symbol for a FET and the circuit symbol for a junction transistor. The circuit symbol 1100 for the semiconductor device 900 defines the upper drain terminal 910, the upper gate terminal 914, the lower gate terminal 916, and the lower drain terminal 912. The circuit symbol 1100 further defines an upper injection terminal 904 and a lower injection terminal 908. The driver 1010 is coupled to the semiconductor device 900 by a plurality of electrical connections. In the example of FIG. 9, the electrical connections to the driver 1010 may comprise connections to all the noted terminals.

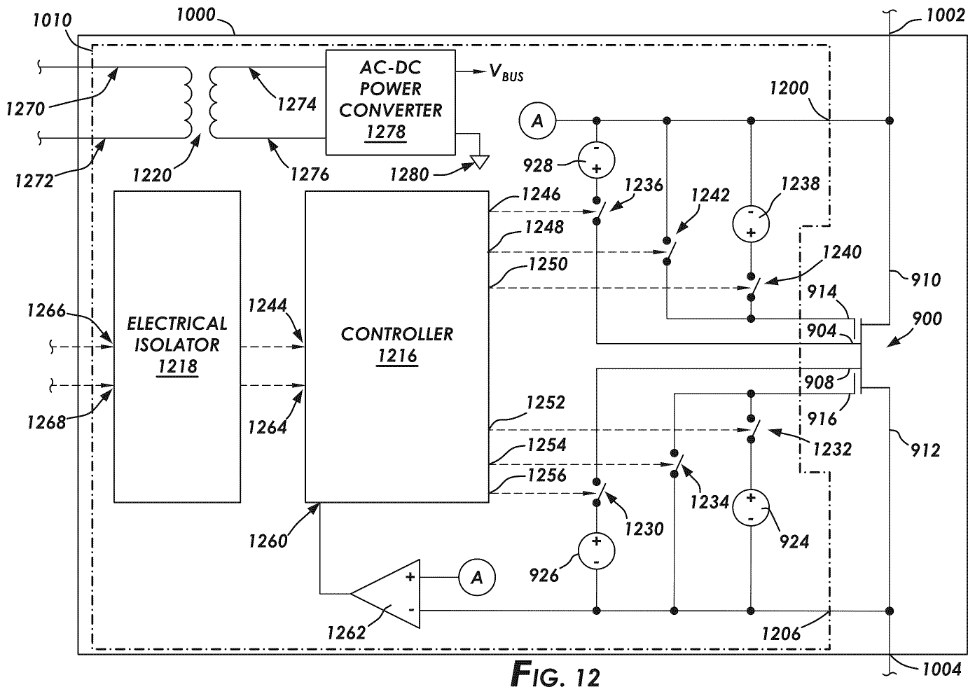

FIG. 12 shows a partial block diagram, partial electrical schematic, of an example switch assembly, such as the switch assembly 1000. In particular, the example switch assembly 1000 comprises the example semiconductor device 900 and the driver 1010. The example driver 1010 defines an upper sense terminal 1200 coupled to the upper drain terminal 910, an upper gate connection coupled to the upper gate terminal 914, an upper injection connection coupled to the upper injection terminal 904, a lower injection connection coupled to the lower injection terminal 908, a lower gate connection coupled to the lower gate terminal 916, and a lower sense terminal 1206 coupled to the lower drain terminal 912.

The example driver 1010 comprises a controller 1216, an electrical isolator 1218, and an isolation transformer 1220. In order to place the semiconductor device 900 in the various operational arrangements of FIGS. 9A-9E, and their reversed-biased equivalents, the example driver 1010 includes a plurality of electrically-controlled switches and sources. In particular, the example driver 1010 comprises the source 926 having a negative lead coupled to the lower terminal 1004 and a positive lead. The controller comprises an electrically-controlled switch 1230 (hereafter just switch 1230) that has a first lead coupled positive lead of the source 926, a second lead coupled to the lower injection terminal 908, and a control input coupled to the controller 1216. The example switch 1230 is shown as a single-pole, single-throw switch, but in practice the switch 1230 may be a FET with the control input being a gate of the FET. Thus, when the switch 1230 is conductive based on assertion of its control input, the source 926 is coupled between the lower drain terminal 910 and the lower injection terminal 908 (e.g., FIGS. 9C and 9D).

The driver 1010 further comprises the source 924 having a negative lead coupled to the lower terminal 1004, and a positive lead. Another electrically-controlled switch 1232 (hereafter just switch 1232) has a first lead coupled to the positive lead of the source 924, a second lead coupled to the lower gate terminal 916, and a control input coupled to the controller 1216. The example switch 1232 is shown as a single-pole, single-throw switch, but in practice, the switch 1232 may be a FET with the control input being the gate of the FET. Thus, when the switch 1232 is conductive, the source 924 is coupled between the lower drain terminal 912 and the lower gate terminal 916 (e.g., FIGS. 9B-9E).

The driver 1010 further comprises electrically-controlled switch 1234 (hereafter just switch 1234) that has a first lead coupled to the lower terminal 1004, a second lead coupled to the lower gate terminal 916, and a control input coupled to the controller 1216. The example switch 1234 is shown as a single-pole, single-throw switch, but in practice, the switch 1234 may be a FET with the control input being the gate of the FET. Thus, when the switch 1234 is conductive, the lower drain terminal 912 is coupled to the lower gate terminal 916 (e.g., FIG. 9A).

Still referring to FIG. 12, the example driver 1010 comprises the source 928 having a negative lead coupled to the upper terminal 1002 and a positive lead. The driver 1010 comprises an electrically-controlled switch 1236 (hereafter just switch 1236) that has a first lead coupled positive lead of the source 928, a second lead coupled to the upper injection terminal 904, and a control input coupled to the controller 1216. The example switch 1236 is shown as a single-pole, single-throw switch, but in practice the switch 1236 may be a FET with the control input being a gate of the FET. Thus, when the switch 1236 is conductive based on assertion of its control input, the source 928 is coupled between the upper drain terminal 910 and the upper injection terminal 904.

The driver 1010 further comprises a source 1238 having a negative lead coupled to the upper terminal 1002, and a positive lead. Another electrically-controlled switch 1240 (hereafter just switch 1240) has a first lead coupled to the positive lead of the source 1238, a second lead coupled to the upper gate terminal 914, and a control input coupled to the controller 1216. The example switch 1240 is shown as a single-pole, single-throw switch, but in practice, the switch 1240 may be a FET with the control input being the gate of the FET. Thus, when the switch 1240 is conductive, the source 1238 is coupled between the upper drain terminal 910 and the upper gate terminal 914.

The driver 1010 further comprises electrically-controlled switch 1242 (hereafter just switch 1242) that has a first lead coupled to the upper terminal 1002, a second lead coupled to the upper gate terminal 914, and a control input coupled to the controller 1216. The example switch 1242 is shown as a single-pole, single-throw switch, but in practice, the switch 1242 may be a FET with the control input being the gate of the FET. Thus, when the switch 1242 is conductive, the upper drain terminal 910 is coupled to the upper gate terminal 914.

The controller 1216 defines a control input 1244, and control outputs 1246, 1248, 1250, 1252, 1254, and 1256 coupled to the control inputs of the switches 1236, 1242, 1240, 1232, 1234, and 1230, respectively. When the control input 1244 is asserted, and the switch assembly 1000 is forward biased, the controller 1216 is designed and constructed to arrange the semiconductor device 900 for conduction from the upper drain terminal 910 to the lower drain terminal 912 (e.g., FIGS. 9B-9E). Further, when the semiconductor device 900 is conductive the controller 1216 may also make the switch 1230 and/or the switch 1236 conductive to inject charge carriers in the drift region of the semiconductor device 900 to lower the voltage drop. When the control input 1244 is de-asserted, and the switch assembly 1000 is still forward biased, the controller 1216 is designed and constructed to make the semiconductor device 900 non-conductive (e.g., FIG. 9A). Stated otherwise, the controller 1216 is configured to selectively arrange the semiconductor device 900 for conduction when the switch assembly 1000 is forward biased.

Oppositely, when the control input 1244 is asserted, and the switch assembly 1000 is reversed biased, the controller 1216 is designed and constructed to arrange the semiconductor device 900 for conduction from the lower drain terminal 912 to the upper drain terminal 910. Further, when the semiconductor device 900 is conductive the controller 1216 may also make the switch 1230 and/or the switch 1236 conductive to inject charge carriers in the drift region of the semiconductor device 900 to lower the voltage drop. When the control input 1244 is de-asserted, and the switch assembly 1000 is still reversed biased, the controller 1216 is designed and constructed to make the semiconductor device 900 non-conductive. Stated otherwise, the controller 1216 is configured to selectively arrange the semiconductor device 900 for conduction when the switch assembly 1000 is reversed biased.

For the example semiconductor device 900 and having a single control input 1244 to the controller 1216, the controller 1216 need not know the polarity of the applied voltage to implement the conductive/non-conductive command associated with the control input 1244. For example, when the control input 1244 is asserted, indicating a desire for conduction, the controller 1216 may arrange assert both the upper and lower gate terminals 914 and 916, and inject carriers by way of both upper and lower injection terminals 904 and 908. Oppositely, when the control input 1244 is de-asserted, indicating a desire for non-conduction, the controller 1216 may de-assert both the upper and lower gate terminals 914 and 916, and refrain from injection charge carriers. Thus, the example controller 1216 need not know the applied polarity.

In other cases, however, it may be beneficial for the controller 1216 to know the applied polarity. To the end of knowing the polarity of the applied voltage, in some examples the controller 1216 may further define a polarity input 1260 that receives a Boolean indication of the applied polarity. In the example driver 1010, a comparator 1262 has a first input coupled to the upper terminal 1002 (the connection shown by bubble “A”) and a second input coupled to the lower terminal 1004. The comparator 1262 defines a compare output coupled to the polarity input 1260. While FIG. 12 shows the first and second inputs coupled directly to the respective terminals, in practice the voltage across the semiconductor device 900 when non-conductive may be large (e.g., 1200V) and thus each of the first and second inputs may be coupled to their respective conduction terminals by way of respective voltage divider circuits. In yet still further cases, the applied polarity may be determined by systems and devices external to the switch assembly 1000, and a Boolean signal sent across the electrical isolator 1218 to the polarity input 1260.

One example that utilizes the knowledge of the applied polarity is selective injection of charge carriers to increase energy efficiency of the switch assembly 1000. For example, when the semiconductor device 900 is forward biased, the injection of charge carriers may take place only by way the upper injection terminal 904. That is, while possible to inject charge carriers by way of both the upper and lower injection terminals 904 and 908 during forward bias, the incremental reduction in voltage drop associated with the injection of charge carriers through the lower injection terminal 908 may not justify the additional energy consumption. Oppositely, when the semiconductor device 900 is reversed biased, the injection of charge carriers may take place only by way the lower injection terminal 908 under the same energy consumption considerations.

In yet still further cases, the controller 1216 may have a second control input 1264. Control input 1244 may be used to control conduction during forward biased conditions, and control input 1266 may be used to control conduction during reverse biased conditions. The control inputs 1244 and 1264 may then be arranged to request conduction in only one applied voltage scenario. For example, if control input 1244 is asserted and control input 1264 is de-asserted, the controller 1216 may make the semiconductor device 900 conductive only during forward biased conditions, including injection of charge carriers. In such a situation, the state of the control inputs 1244 and 1264 may not change as the applied voltage changes; instead, the controller 1216 changes the conductive/non-conductive arrangement responsive to the state of the polarity input 1260.

The controller 1216 may be individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations, configured to read the control inputs 1244 and 1264, read the polarity input 1260 when implemented, and drive control outputs to implement the conductive state of the semiconductor device 900.

In example systems, the switch assembly 1000 is electrically floated. In order to receive the control inputs 1244 and 1264 in the electrical domain of the switch assembly 1000, the example driver 1010 implements the electrical isolator 1218. The example electrical isolator 1218 may take any suitable form, such as optocouplers or capacitive isolation devices. Regardless of the precise nature of the electrical isolator 1218, an external control signal (e.g., Boolean signal) may be coupled to the control input 1266 of the electrical isolator 1218, and control input 1266 may be the control terminal 1006. The electrical isolator 1218, in turn, passes the control signal through to the electrical domain of the switch assembly 1000. In the example, the external control signal is passed through to become the control input 1244 of the controller 1216.

When control input 1264 is implemented, another external control signal (e.g., Boolean signal) may be coupled to the control input 1268 of the electrical isolator 1218, and control input 1268 may be the control terminal 1008. The electrical isolator 1218, in turn, passes the control signal through to the electrical domain of the switch assembly 1000. In the example, the external control signal is passed through to become the control input 1264 of the controller 1216.

Turning now to the isolation transformer 1220, various devices within the switch assembly 1000 may use operational power. For example, the controller 1216 may use a bus voltage and power to enable implementation of the various modes of operation of the semiconductor device 900. Further, the sources 924, 926, 928, and 1238 may be implemented in the form of switching power converters, or current sources also in the form of switching power converters. The switching power converters implementing the sources may use bus voltage and power. In order to provide operational power within the electrical domain of the switch assembly 1000, the isolation transformer 1220 is provided. External systems (not specifically shown) may provide an alternating current (AC) signal across the primary leads 1270 and 1272 of the isolation transformer 1220 (e.g., 15V AC). The isolation transformer 1220 creates an AC voltage on the secondary leads 1274 and 1276. The AC voltage on the secondary of the isolation transformer 1220 may be provided to an AC-DC power converter 1278, which rectifies the AC voltage and provides power by way of bus voltage V_{BUS} (e.g., 3.3V, 5V, 12V) with respect to a reference voltage or common 1280. The power provided by the AC-DC power converter 1278 may be used by the various components of the switch assembly 1000. In other cases, multiple isolation transformers may be present (e.g., one for each side of the bipolar junction device). Further still, a single isolation transformer with multiple secondary windings may be used.

The sources 924 and 1238 as shown as voltage sources consistent with operation of the gates. That is, very little current flows to the gate structures to create the electric fields used to create the channel regions. Sources 926 and 928 are also shown as voltage sources, but such should not be construed as limiting. The sources 926 and 928 may be single-level voltage sources, multiple-level voltage sources, single-level current sources, and/or multiple-level current sources.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A bipolar junction device comprising:
a substrate defining a first side and a second side;
a field-effect structure defined on the first side, the field-effect structure comprising:
a channel region;
a gate region in operational relationship to the channel region, and electrically insulated from the channel region; and
a cathode region forming a junction with the channel region; and
a bipolar junction structure defined on the second side, the bipolar junction structure comprising:
an injection region forming a junction with the substrate; and
an anode region in operational relationship to the substrate.

2. The bipolar junction device of claim 1 wherein the gate region comprises a metal electrically insulated from the channel region.

3. The bipolar junction device of claim 1 wherein the substrate is N-type, the channel region is P-type, and the cathode region is N-type.

4. The bipolar junction device of claim 3 wherein the injection region is P-type, and the anode region is N-type.

5. The bipolar junction device of claim 4 wherein the injection region has a depth, after activation, of about 10 microns.

6. The bipolar junction device of claim 4 wherein the injection region has a depth, after activation, of about 5 microns.

7. The bipolar junction device of claim 1 further comprising a cathode metal electrically contacting the cathode region and the channel region.

8. The bipolar junction device of claim 7 wherein the cathode metal forms an ohmic contact with the cathode region.

9. A switch assembly, comprising:
an upper terminal, a lower terminal, and a control terminal;
a bipolar junction device comprising:
a channel region on a first side of a substrate, the channel region coupled to the lower terminal;
a cathode region in operational relationship to the channel region;
a gate region in operational relationship to the both the channel region and the cathode region;
an anode region on a second side of the substrate opposite the first side, the anode region coupled to the upper terminal; and
an injection region on the second side of the substrate; and
a driver coupled to control terminal, the cathode region, and the gate region, the driver configured to:
during periods of time when the switch assembly is forward biased and the control terminal is asserted, arrange the bipolar junction device to conduct a forward current from the upper terminal, through the anode region, and to the lower terminal; and
during periods of time when the switch assembly is forward biased and the control terminal is de-asserted, arrange the bipolar junction device to block current from the upper terminal to the lower terminal.

10. The switch assembly of claim 9 wherein, during periods of time when the switch assembly is reverse biased, the bipolar junction device non-selectively conducts a reverse current from the lower terminal, to the cathode region, and then to the upper terminal.

11. The switch assembly of claim 9 wherein the driver is further configured to, during periods of time when the switch assembly is forward biased and the control terminal is asserted, inject charge carriers into substrate by way of the injection region.

12. The switch assembly of claim 9 wherein the driver is further configured to, during periods of time when the switch assembly is reverse biased, inject charge carriers into the substrate by way of the injection region.

13. A semiconductor device comprising:
a substrate defining a first side and a second side;
an upper field-effect transistor on the first side, the upper field-effect transistor defines an upper channel region, an upper gate structure in operational relationship to the upper channel region, and an upper drain region that forms a junction with the upper channel region;
an upper injection region on the first side;
a lower field-effect transistor on the second side, the lower field-effect transistor defines a lower channel region, a lower gate structure in operational relationship to the lower channel region, and a lower drain region that forms a junction with the lower channel region;
a lower injection region on the second side; and
a drift region within in the substrate between the upper channel region and the lower channel region.

14. The semiconductor device of claim 13:
wherein the upper field-effect transistor comprises:
an upper ridge defined between a first trench region and a second trench region, the upper ridge defines a first sidewall associated with the first trench region, a second sidewall associated with the second trench region, and an upper crest;
the upper drain region and the upper channel region within the upper ridge;
an upper-drain metal disposed on the upper crest and electrically coupled to the upper drain region; and
the upper gate structure disposed on the second sidewall in operational relationship to the upper channel region; and
wherein the upper injection region is a doped region associated with a bottom of the first trench region.

15. The semiconductor device of claim 14 wherein at least one of:
the upper-drain metal is in ohmic contact with the upper drain region; and
the first trench region and the second trench region are at least one selected from a group comprising: portions of an upper trench; and portions of a first trench and a second trench, respectively.

16. The semiconductor device of claim 14:
wherein the lower field-effect transistor further comprises:
a lower ridge defined between a third trench region and a fourth trench region, the lower ridge defines a third sidewall associated with the third trench region, a fourth sidewall associated with the fourth trench region, and a lower crest;
the lower drain region and the lower channel region disposed within the lower ridge;
a lower-drain metal disposed on the lower crest and electrically coupled to the lower drain region; and
the lower gate structure disposed on the fourth sidewall in operational relationship to the lower channel region; and
wherein the lower injection region is a doped region associated with a bottom of the third trench region.

17. The semiconductor device of claim 16 wherein at least one of:
the lower-drain metal is in ohmic contact with the lower drain region; and
the third trench region and the fourth trench region are at least one selected from a group comprising: portions of a lower trench; and portions of a first trench and a second trench, respectively.

18. The semiconductor device of claim 13:
wherein the upper field-effect transistor comprises:
an upper ridge defined between a first trench region and a second trench region, the upper ridge defines a first sidewall associated with the first trench region, a second sidewall associated with the second trench region, and an upper crest;
the upper drain region and the upper channel region disposed within the upper ridge;
an upper-drain metal disposed on the upper crest and electrically coupled to the upper drain region; and
the upper gate structure comprising a first gate structure within the first trench region and in operational relationship to the upper channel region, and a second gate structure within the second trench region and in operation relationship to the upper channel region;
wherein the first trench region defines an adjacent crest, and the upper injection region disposed within an adjacent crest.

19. The semiconductor device of claim 13:
wherein the upper field-effect transistor comprises:
a first trench defining a first sidewall associated with a first terrace, a second sidewall associated with a second terrace, and a bottom;
the upper drain region and the upper channel region disposed within the substrate of the first terrace;
an upper-drain metal disposed on the first terrace and electrically coupled to the upper drain region; and
the upper gate structure comprising a first gate structure within the first trench and in operational relationship to the upper channel region; and
wherein the upper injection region is a doped region associated with the bottom of the first trench.

20. The semiconductor device of claim 19 further comprising:
an adjacent field-effect transistor on the first side, the adjacent field-effect transistor comprising:
an upper drain region and an upper channel region disposed within the substrate of the second terrace;
an upper-drain metal disposed on the second terrace and electrically coupled to the upper drain region of the adjacent field-effect transistor; and
an adjacent gate comprising a first gate structure within the first trench and in operational relationship to the upper channel region of the adjacent field-effect transistor.
